(19) United States
(12) Patent Application Publication
(10) Pub. No.: US 2004/0082174 A1
(43) Pub. Date: Apr. 29, 2004

(54) Method of wire bonding of a semiconductor device for resolving oxidation of copper bonding pad

(76) Inventors: Wen-Lo Shieh, Taipei (TW); Fu-Yu Huang, Taipei (TW); Ning Huang, Taipei (TW); Hui-Pin Chen, Taipei (TW); Shu-Wan Lu, Taipei (TW); Zhe-Sung Wu, Taipei (TW); Chih-Yu Tsai, Taipei (TW); Mei-Hua Chen, Taipei (TW); Chia-Ling Lu, Taipei (TW); Yu-Ju Wang, Taipei (TW); Yu-Chun Huang, Taipei (TW); Tzu-Lin Liu, Taipei (TW); Wen-Tsung Weng, Taipei (TW); Ya-Hsin Tseng, Taipei (TW)

Correspondence Address: Wen-Lo Shieh, PO Box 82-144, Taipei, TW

(21) Appl. No.: 10/689,026

(22) Filed: Oct. 21, 2003

(30) Foreign Application Priority Data
Oct. 23, 2002 (TW) 091125383

(51) Int. Cl. H01L 21/302; H01L 21/461

(52) U.S. Cl. 438/689

(57) ABSTRACT

A method of wire bonding of a semiconductor device for resolving oxidation of copper bonding pad is disclosed. The method comprises the steps of exposing the copper bonding pad of a wafer which has been completed with semiconductor circuit fabrication; covering the copper bonding pad of the wafer with a protective anti-oxidization film which will be vaporized when heated; performing wire bonding directly without requiring the removal of the protective film, employing ultrasonic vibration energy, pressurizing deformation energy and heat energy in the course of bonding to vaporize the protective film so that the metal wire and the copper pad form a large area intermetallic compound layer for bonding.

### BACKGROUND OF THE INVENTION

(a) Field of the Invention

The present invention relates to a method of wire bonding of a semiconductor device for resolving oxidation of copper bonding pad. The oxides on the copper bonding pad does not require additional treatment and the wire bonding can be directly performed and the present method ensures no oxide remains on the wire bonding surface.

(b) Description of the Prior Art

Even though new bonding methods of connecting bonding pads on the wafer and the substrate have been proposed, wire bonding technique is the current mainstream technology, and the current wire bonding technique which can be performed with high speed and high precision is regarded as a point-to-point bonding method which is economical with respect to fabrication.

FIGS. 1 and 1A show a typical conventional wire bonding method on the bonding pad of the wafer. Generally, the exposed copper bonding pad 11′ of a wafer 1′ can be easily oxidized. The copper bonding pad surface is formed into a layer of oxide on the copper bonding pad oxidized layer 12′. In the current wire bonding method, the oxide of the copper bonding pad 11′ is normally ignored by the manufacturer and the metal wire 23′ forcefully breaks the oxidized layer 12′ on the bonding pad in the course of wiring fabrication. If the bonding point is spherical bonding, by using the slip planes formed by the deformation of the metal wire 23′, each slip plane embeds the oxidized layer 12′ while making a connection between the metal wire 23′ and the copper bonding pad 11′. This method follows the wiring bonding fabrication method for aluminum bonding pad. However, the oxidation rate of aluminum and copper is different. The oxidation speed of the copper bonding pad surface is fast and the accumulated oxidized layer is relatively thicker and it is ineffective to push the oxides away. The coverage of deformed metal wire may not be able to cover the oxides entirely and cause poor bondability. If another process is to be introduced to remove the oxides on the copper bonding pad it will incur additional cost. Therefore it is an object of the present invention to provide a method of wire bonding of a semiconductor device which can solve the drawbacks as mentioned above.

### SUMMARY OF THE NVENTION

Accordingly, it is an object of the present invention to provide a method of wire bonding of a semiconductor device for resolving oxidation of copper bonding pad, the method comprising the steps of:

A wafer with a copper bonding pad being provided;

covering the copper bonding pad of the wafer with an anti-oxidization protective film which will be vaporized when heated; and

performing wire bonding directly without requiring the removal of the protective film, employing ultrasonic vibration energy, pressurizing deformation energy and heat energy in the course of bonding to vaporize the protective film so that the metal wire and the copper bonding pad form into a large intermetallic compound layer for bonding.

Yet another object of the present invention is to provide a method of wire bonding of a semiconductor device for resolving oxidation of copper bonding pad, wherein the formation of oxides on the copper bonding pad of the wafer is mitigated, and the yield and throughput of the fabrication process are greatly improved.

The foregoing object and summary provide only a brief introduction to the present invention. To fully appreciate these and other objects of the present invention as well as the invention itself, all of which will become apparent to those skilled in the art, the following detailed description of the invention and the claims should be read in conjunction with the accompanying drawings. Throughout the specification and drawings identical reference numerals refer to identical or similar parts.

Many other advantages and features of the present invention will become manifest to those versed in the art upon making reference to the detailed description and the accompanying sheets of drawings in which a preferred structural embodiment incorporating the principles of the present invention is shown by way of illustrative example.

### BRIEF DESCRIPTION OF THE DRAWINGS

The features of the invention believed to be novel and the element characteristics of the invention are set forth with particularity in the appended claims. The invention may best be understood by reference to the detailed description which follows taken in conjunction with the accompanying drawing in which:

FIG. 1 is a schematic view showing a conventional wire bonding of copper bonding pad.

FIG. 1 is an enlarged view of a portion of FIG. 1.

FIGS. 2A to 2D are schematic views showing the wire bonding of copper bonding pad in accordance with a preferred embodiment of the present invention.

FIG. 2E is an enlarged view of a portion of FIG. 2D.

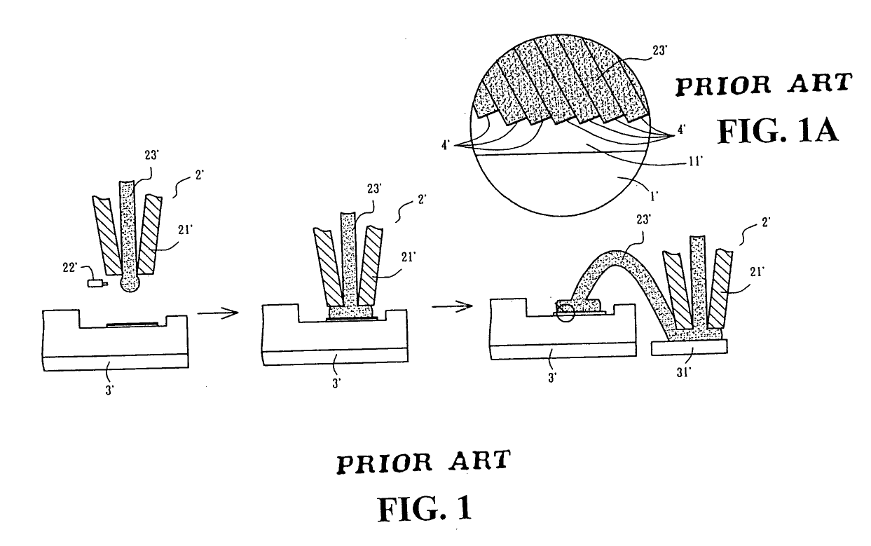

### DETAILED DESCRIPTION OF THE PRESENT INVENTION

The following descriptions are of exemplary embodiments only, and are not intended to limit the scope, applicability or configuration of the invention in any way. Rather, the following description provides a convenient illustration for implementing exemplary embodiments of the invention. Various changes to the described embodiments may be made in the function and arrangement of the elements described without departing from the scope of the invention as set forth in the appended claims.

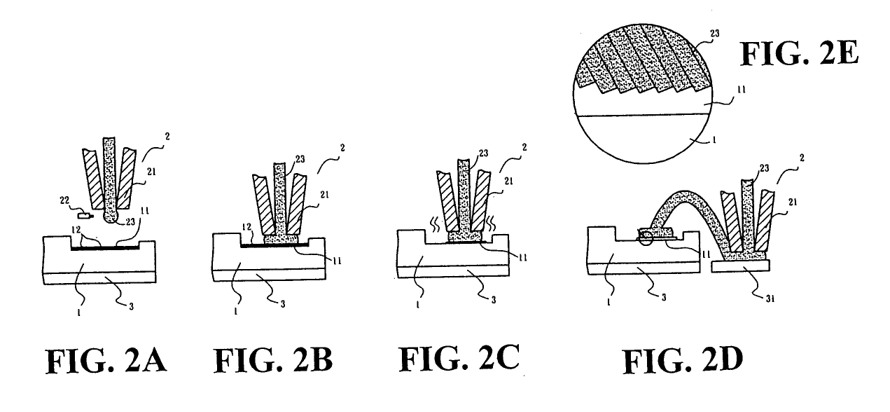

In describing the preferred embodiment of the present invention, reference will be made herein to FIG. 2 of the drawings in which like numerals refer to like features of the invention.

Referring to FIGS. 2A, 2B, 2C, 2D and 2E, there is shown a method of wire bonding of a semiconductor device for resolving oxidation of copper bonding pad, the method comprising the steps of:

(a) a wafer 1 with copper bonding pad 11 being provided;

(b) covering the copper bonding pad 11 of the wafer with an anti-oxidization protective film 12 which will be vaporized when heated in the course of fabricating copper bonding pad 11 of the wafer 1 to protect the copper bonding pad 11 from being oxidized, providing a longer shelf-life; and

(c) performing wire bonding directly without requiring the removal of the protective film 12, employing mechanical energy such as ultrasonic vibration energy, pressurizing deformation energy and heat energy in the course of bonding to vaporize the protective film 12 so that the metal wire 23 and the copper bonding pad 11 form into a large area intermetallic compound layer for bonding.

In accordance with the present invention, a bonding pad protective film is used to cover the copper bonding pad surface which is prone to oxidize. Without incurring the additional cost of removing the protective film, wire bonding can be performed by employing the heat energy that evolved in the course of fabrication to vaporize the protective film, forming into pure electrical bonding surface with no residue of oxides. Therefore the present invention solves the drawbacks of the conventional method of forming oxides on the copper bonding pad.

It will be understood that each of the elements described above, or two or more together may also find a useful application in other types of methods differing from the type described above.

While certain novel features of this invention have been shown and described and are pointed out in the annexed claim, it is not intended to be limited to the details above, since it will be understood that various omissions, modifications, substitutions and changes in the forms and details of the device illustrated and in its operation can be made by those skilled in the art without departing in any way from the spirit of the present invention.

1. A method of wire bonding of a semiconductor device for resolving oxidation of copper bonding pad, the method comprising the steps of:
a wafer 1 with copper bonding pad 11 being provided;
covering the copper bonding pad 11 of the wafer 1 with an anti-oxidization protective film 12 which will be vaporized when heated in the course of fabricating copper bonding pad 11 of the wafer 1 to protect the copper bonding pad 11 from being oxidezed, providing a longer shelf-life; and
performing wire bonding directly without requiring the removal of the protective film 12, employing mechanical energy such as ultrasonic vibration energy, pressurizing deformation energy and heat energy in the course of bonding to vaporize the protective film 12 so that the metal wire 23 and the copper bonding pad 11 form into a large area intermetallic compound layer for bonding.
